(19) United States
(12) Patent Application Publication
(10) Pub. No.: US 2022/0334167 A1
(43) Pub. Date: Oct. 20, 2022

(54) METHOD FOR DETECTING DEFECTS IN GALLIUM NITRIDE HIGH ELECTRON MOBILITY TRANSISTOR

(71) Applicant: NATIONAL SUN YAT-SEN UNIVERSITY, Kaohsiung (TW)

(72) Inventors: Ting-Chang CHANG, Kaohsiung (TW); Hao-Xuan ZHENG, Kaohsiung (TW); Yu-Shan LIN, Kaohsiung (TW); Fu-Yuan JIN, Kaohsiung (TW); Fong-Min CIOU, Kaohsiung (TW); Mao-Chou TAI, Kaohsiung (TW); Yun-Hsuan LIN, Kaohsiung (TW); Wei-Chen HUANG, Kaohsiung (TW); Wen-Chung CHEN, Kaohsiung (TW)

(21) Appl. No.: 17/343,804

(22) Filed: Jun. 10, 2021

(30) Foreign Application Priority Data
Apr. 14, 2021 (TW) 110113424

(51) Int. Cl. G01R 31/26; G01R 31/265

(52) U.S. Cl. CPC G01R 31/2601; G01R 31/2656; H01L 29/2003

(57) ABSTRACT

A method for detecting defects in a GaN high electron mobility transistor is disclosed. The method includes steps of measuring a plurality of electrical characteristics of a GaN high electron mobility transistor, measuring the plurality of electrical characteristics after performing a deterioration test on the GaN high electron mobility transistor, irradiating the GaN high electron mobility transistor in turns with a plurality of light sources with different wavelengths and measuring the plurality of electrical characteristics after each irradiation of the GaN high electron mobility transistor by each of the plurality of light sources, and comparing changes of the plurality of electrical characteristics measured in the above steps to determine the defect location of the GaN high electron mobility transistor.

### CROSS REFERENCE TO RELATED APPLICATION

The application claims the benefit of Taiwan application serial No. 110113424, filed on Apr. 14, 2021, and the entire contents of which are incorporated herein by reference.

### BACKGROUND OF THE INVENTION

### 1. Field of the Invention

The present invention generally relates to an electronic component test process and, more particularly, to a method for detecting defects in GaN high electron mobility transistor, which can identify the defect locations quickly.

### 2. Description of the Related Art

In recent years, industries such as electric vehicles and 5G communications develop rapidly and increase the specification performance and demands for electronic components. High-power, low-consumption and high-frequency electronic components have market advantages. Among them, gallium nitride (GaN) has high breakdown voltage, high electron saturation drift rate, low resistivity, good chemical corrosion resistance and good thermal stability. Thus, it is an ideal semiconductor material. However, the process defects of hot carrier injection into the transistor often occur when the high electron mobility transistor (HEMT) with gallium nitride as the main material is under the working conditions of high voltage and current. Thus, it results in the decrease of the on-state current of the transistor, the drift of the initial voltage, and the shortened usage life. When the transistor is used as a switch component, the deviated value of the switching condition would cause misinterpretation and affect the signal transmission of the loop.

In order to improve the defect of GaN high electron mobility transistors, a test process is performed on transistors after production to screen out transistors which do not meet specifications, and to identify the defect locations to check the front-end process needed to be improved. However, the defect locations of the GaN high electron mobility transistor have a wide distribution, and it is difficult to accurately identify the location and cause of the defects. Moreover, the conventional defect detection method uses material analysis or electrical variable temperature extraction analysis, so the process of detection and analysis is complicated and slow, which is not suitable for large-scale and fast production flow in factories.

In light of the above problem, it is necessary to improve the conventional method for detecting defects in GaN high electron mobility transistor.

### SUMMARY OF THE INVENTION

To solve the problems mentioned above, it is an objective of the present invention to provide a method for detecting defects in GaN high electron mobility transistor, which can identify the defects of components quickly.

It is another objective of the present invention to provide a method for detecting defects in GaN high electron mobility transistor, which can accurately identify the location distribution of the defects.

It is yet another objective of the present invention to provide a method for detecting defects in GaN high electron mobility transistor, which can provide information on improving the production process.

As used herein, the term “a”, “an”, or “one” for describing the number of the elements and members of the present invention is used for convenience, provides the general meaning of the scope of the present invention, and should be interpreted to include one or at least one.

Furthermore, unless explicitly indicated otherwise, the concept of a single component also includes the case of plural components.

A method for detecting defects in GaN high electron mobility transistor according to an embodiment includes steps of measuring a plurality of electrical characteristics of a GaN high electron mobility transistor, measuring the plurality of electrical characteristics after performing a deterioration test on the GaN high electron mobility transistor, irradiating the GaN high electron mobility transistor in turns with a plurality of light sources with different wavelengths and measuring the plurality of electrical characteristics after each irradiation of the GaN high electron mobility transistor by each of the plurality of light sources, and comparing changes of the plurality of electrical characteristics measured in the above steps to determine a defect location of the GaN high electron mobility transistor.

Accordingly, the method for detecting defects in GaN high electron mobility transistor according to the embodiment determines whether there are defects in the transistor and identifies the location distribution of the defects by irradiating lights of various wavelengths and measuring the electrical characteristic changes of the transistor, which can accurately determine the defects and distribution thereof, ensuring the effects of improving the process of component production and increasing the efficiency of product inspection.

In an example, the plurality of electrical characteristics is an on- state current and an initial voltage of the GaN high electron mobility transistor. Thus, by observing the changes of the on-state current and the initial voltage, the information of carrier injection defects can be obtained, ensuring the effect of identifying whether there are defects.

In an example, one of the plurality of light sources emits a visible light within a wavelength range between 400 nm and 700 nm and is configured to incur a response at an interface between a silicon nitride layer and an aluminum gallium nitride layer of the GaN high electron mobility transistor. Thus, the visible light can act on specific materials, ensuring the effect of changing the electrical characteristics of specific structures.

In an example, one of the plurality of light sources emits an ultraviolet light with a wavelength of 365 nm and is configured to incur a response at a gallium nitride layer of the GaN high electron mobility transistor. Thus, the ultraviolet light can act on specific materials, ensuring the effect of changing the electrical characteristics of specific structures.

In an example, one of the plurality of light sources emits an ultraviolet light with a wavelength of 265 nm and is configured to incur a response at an aluminum gallium nitride layer of the GaN high electron mobility transistor. Thus, the ultraviolet light with different wavelengths can act on different materials, ensuring the effect of changing the electrical characteristics of different defect locations respectively.

In an example, the GaN high electron mobility transistor includes an electron supply layer laminated on a channel layer, a gate electrode located on the electron supply layer, and a passivation layer covering the electron supply layer and the gate electrode. The defect location of the GaN high electron mobility transistor includes a power supply zone, a buffer zone, a passivation zone and a drift zone. Among them, the power supply zone is located in the electron supply layer and under the gate electrode. The buffer zone and the drift zone are located in the channel layer. The buffer zone is located under the gate electrode. The drift zone is located aside the buffer zone. The passivation zone is located in the passivation layer. Thus, the plurality of defect locations can be classified according to the material characteristics and the relative position with the electrodes, ensuring the effect of accurately identifying the defect locations.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a lamination cross-sectional diagram of a defect location according to a preferred embodiment of the present invention.

FIG. 2 is a characteristic curve diagram of defect detection according to the preferred embodiment of the present invention.

FIG. 3 is a characteristic curve diagram of another defect location as compared with FIG. 2.

In the various figures of the drawings, the same numerals designate the same or similar parts. Furthermore, when the terms “top”, “bottom”, “increase”, “reduce”, “side” and similar terms are used hereinafter, it should be understood that these terms have reference only to the structure shown in the drawings as it would appear to a person viewing the drawings, and are utilized only to facilitate describing the invention, rather than restricting the invention.

### DETAILED DESCRIPTION OF THE INVENTION

A method for detecting defects in GaN high electron mobility transistor according to a preferred embodiment of the present invention includes steps of performing a withstand voltage test on a GaN high electron mobility transistor, and irradiating the GaN high electron mobility transistor with several light sources in turn.

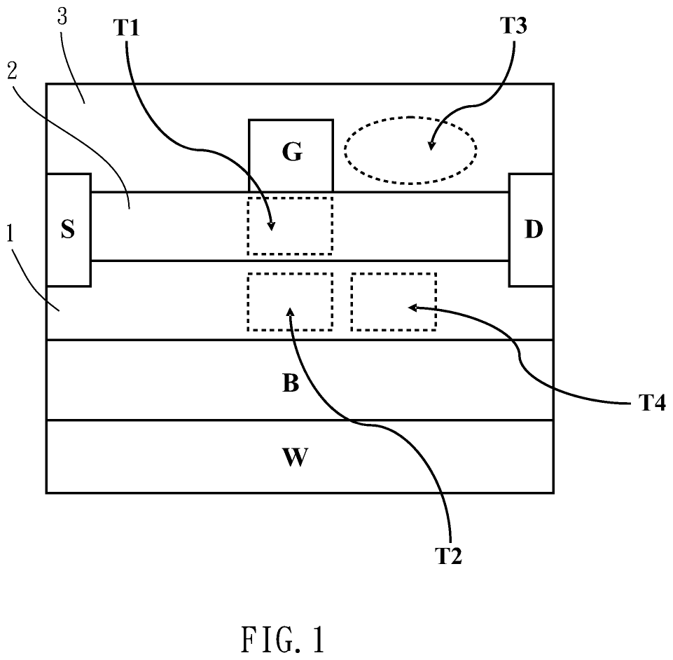

Referring to FIG. 1, the GaN high electron mobility transistor is sequentially stacked from bottom to top with a silicon substrate W, a buffer layer B, a channel layer 1, an electron supply layer 2 and a passivation layer 3. Both ends of the channel layer 1 and the electron supply layer 2 are respectively electrically connected to a source electrode S and a drain electrode D. A gate electrode G is further disposed on the electron supply layer 2. The passivation layer 3 covers the electron supply layer 2, the gate electrode G, the source electrode S, and the drain electrode D.

The defect location of the GaN high electron mobility transistor includes a power supply zone T1, a buffer zone T2, a passivation zone T3, and a drift zone T4. The power supply zone T1 is located in the electron supply layer 2 and under the gate electrode G, and the material of the power supply zone T1 may be aluminum gallium nitride (AlGaN). The buffer zone T2 and the drift zone T4 are located in the channel layer 1. The buffer zone T2 is located under the gate electrode G. The drift region T4 is located aside the buffer zone T2. The material of the buffer zone T2 and the drift zone T4 may be gallium nitride (GaN). The passivation zone T3 is located in the passivation layer 3, and the material of the passivation zone T3 may be silicon nitride (SiN).

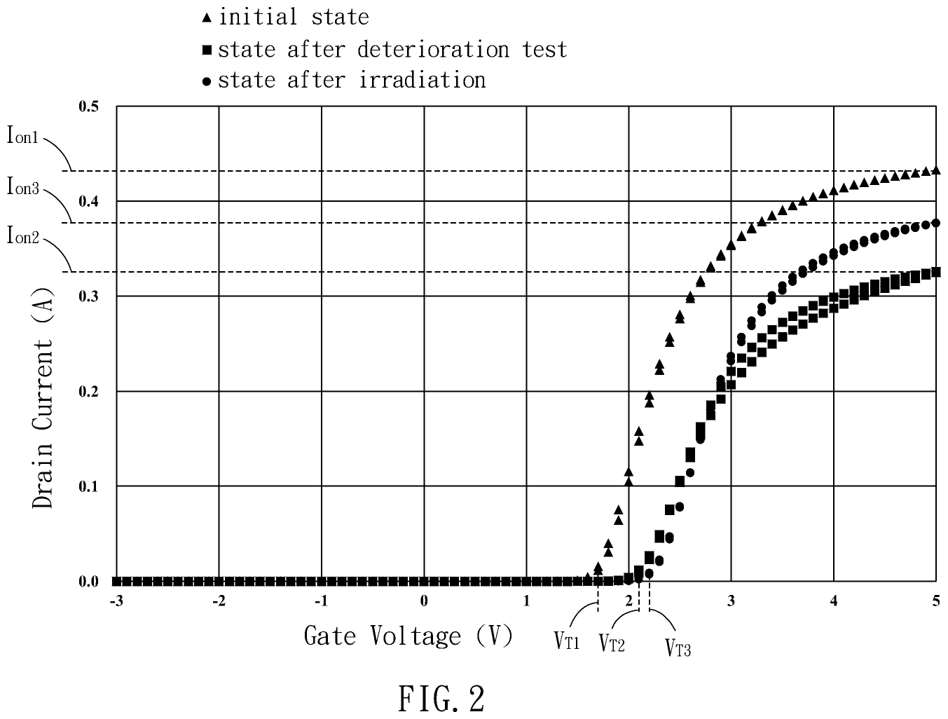

Referring to FIGS. 1 and 2, gradually increasing gate voltages are provided to the gate electrode G of the GaN high electron mobility transistor, and the changes of the drain current at the drain electrode D are measured. When the gate voltage is greater than an initial voltage, the drain current begins to increase drastically. Further, the increasing trend of the drain current stabilizes when reaching a value of an on-state current. As shown in FIG. 2, the initial state of the GaN high electron mobility transistor is measured by an electrical test after the transistor is produced. The first initial voltage V_{T1} and the first on-state current Iₒₙ₁ of the transistor in the initial state may be obtained from the characteristic curve diagram recorded in the electrical test.

After obtaining the electrical characteristic of the GaN high electron mobility transistor in the initial state, the degradation test of the GaN high electron mobility transistor can be performed by placing the transistor in a harsh environment, such as 1.5 times the working voltage. Therefore, the transistor is forced to degrade in a short time, so as to predict the reliability and life of the transistor under normal working conditions. By analyzing the degraded transistor, the defect mode can be determined and serve as a reference for improving process. As shown in FIG. 2, the second initial voltage V_{T2} and the second on-state current Iₒₙ₂ of the transistor in the state after the deterioration test may be obtained again from the electrical test. Compared with the first initial voltage V_{T1} and the first on-state current Iₒₙ₁, the second initial voltage V_{T2} shifts in the positive direction, while the second on-state current Ione decreases.

In addition, photons can promote the escape of the carriers injected into the defects, so that the GaN high electron mobility transistor after deterioration can restore its electrical characteristics to a limited extent. As shown in FIG. 2, the third initial voltage V_{T3} and the third on-state current Iₒₙ₃ of the transistor in the state after irradiation and deterioration may be obtained again from the electrical test. The third on-state current Iₒₙ₃ is higher than the second on-state current Iₒₙ₂, but is still lower than the first on-state current Iₒₙ₁.

According to the changes in the electrical characteristic of the GaN high electron mobility transistor among the initial state, the state after the degradation test, and the state after irradiation, the defect locations can be determined. When a defect is located in the power supply zone T1 and the buffer zone T2, the caused changes in electrical characteristic are the drift of the initial voltage and the increasing or reducing of the on-state current. When the defect is located in the passivation zone T3 and the drift zone T4, the caused changes in electrical characteristic are the reducing and restoring of the on-state current. In addition, irradiating visible light with a wavelength range between 400 nm and 700 nm can incur a response at an interface between a silicon nitride layer and an aluminum gallium nitride layer. Irradiating the transistor with ultraviolet light with wavelength of 365 nm can incur a response at a gallium nitride layer. Irradiating the transistor with ultraviolet light with wavelength of 265 nm can incur a response at an aluminum gallium nitride layer. Thereby, carrier injection defects at the locations with the occurrence of light response can be reduced.

Referring to FIGS. 1 and 2, the second on-state current Iₒₙ₂ has reduced in the GaN high electron mobility transistor after the deterioration test. If the third on-state current Iₒₙ₃ increases after the irradiation by visible light, it can be determined that the defect is located in the passivation zone T3. If the third on-state current Iₒₙ₃ increases after the irradiation by ultraviolet light, it can be determined that the defect is located in the drift zone T4.

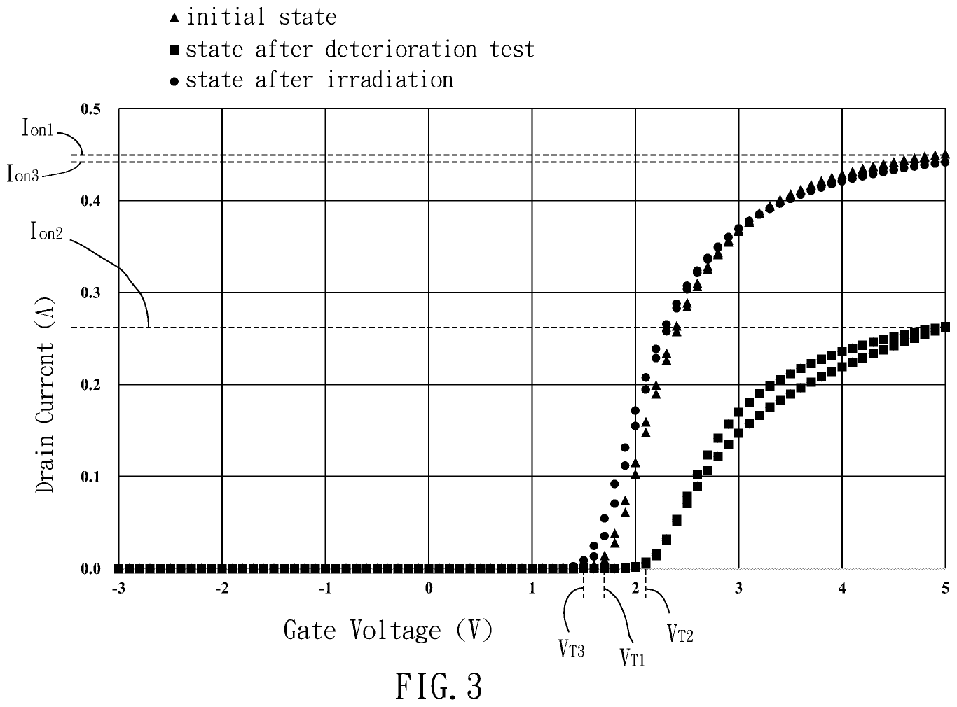

Referring to FIGS. 1 and 3, the second initial voltage V_{T2} has increased and the second on-state current Iₒₙ₂ has reduced in the GaN high electron mobility transistor after the deterioration test. If the third initial voltage V_{T3} reduces and the third on-state current Ion3 increases after the irradiation by ultraviolet light with wavelength of 365 nm, it can be determined that the defect is located in the buffer zone T2. If the third initial voltage V_{T3} reduces and the third on-state current Iₒₙ₃ increases after the irradiation by ultraviolet light with wavelength of 265 nm, it can be determined that the defect is located in the power supply zone T1.

Based on the above, the method for detecting defects in GaN high electron mobility transistor according to the present invention determines whether there are defects in the transistor and identifies the location distribution of the defects by irradiating lights of various wavelengths and measuring the electrical characteristic changes of the transistor, which can accurately determine the defects and distribution thereof, ensuring the effects of improving the process of component production and increasing the efficiency of product inspection.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A method for detecting defects in a GaN high electron mobility transistor comprising:
measuring a plurality of electrical characteristics of a GaN high electron mobility transistor;
measuring the plurality of electrical characteristics after performing a deterioration test on the GaN high electron mobility transistor;
irradiating the GaN high electron mobility transistor in turns with a plurality of light sources with different wavelengths and measuring the plurality of electrical characteristics after each irradiation of the GaN high electron mobility transistor by each of the plurality of light sources; and
comparing changes of the plurality of electrical characteristics that are measured to determine a defect location of the GaN high electron mobility transistor.

2. The method as claimed in claim 1, wherein the plurality of electrical characteristics is an on-state current and an initial voltage of the GaN high electron mobility transistor.

3. The method as claimed in claim 1, wherein one of the plurality of light sources emits a visible light within a wavelength range between 400 nm and 700 nm and is configured to incur a response at an interface between a silicon nitride layer and an aluminum gallium nitride layer of the GaN high electron mobility transistor.

4. The method as claimed in claim 1, wherein one of the plurality of light sources emits an ultraviolet light with a wavelength of 365 nm and is configured to incur a response at a gallium nitride layer of the GaN high electron mobility transistor.

5. The method as claimed in claim 1, wherein one of the plurality of light sources emits an ultraviolet light with a wavelength of 265 nm and is configured to incur a response at an aluminum gallium nitride layer of the GaN high electron mobility transistor.

6. The method as claimed in claim 1, wherein the GaN high electron mobility transistor comprises an electron supply layer laminated on a channel layer, a gate electrode located on the electron supply layer, and a passivation layer covering the electron supply layer and the gate electrode, wherein the defect location of the GaN high electron mobility transistor includes a power supply zone, a buffer zone, a passivation zone and a drift zone, wherein the power supply zone is located in the electron supply layer and under the gate electrode, the buffer zone and the drift zone are located in the channel layer, with the buffer zone located under the gate electrode and the drift zone located aside the buffer zone, and the passivation zone is located in the passivation layer.
